(19) United States
(12) Patent Application Publication
(10) Pub. No.: US 2021/0066396 A1
(43) Pub. Date: Mar. 4, 2021

(54) SELF-POWERED ORGANOMETALLIC HALIDE PEROVSKITE PHOTODETECTOR WITH HIGH DETECTIVITY

(71) Applicant: KING ABDULLAH UNIVERSITY OF SCIENCE AND TECHNOLOGY, Thuwal (SA)

(72) Inventors: Jr-Hau HE, Thuwal (SA); Siu-Fung LEUNG, Thuwal (SA); Vincent HSIAO, Thuwal (SA)

(21) Appl. No.: 16/958,004

(22) PCT Filed: Nov. 14, 2018
(86) PCT No.: PCT/IB2018/058973

§ 371 Date: Jun. 25, 2020

Related U.S. Application Data
(60) Provisional application No. 62/614,639, filed on Jan. 8, 2018.

(51) Int. Cl. H01L 27/30; H01G 9/20; H02N 1/04; H01L 51/00

(52) U.S. Cl. CPC H01L 27/305; H01L 51/0003; H02N 1/04; H01G 9/2009

(57) ABSTRACT

A self-powered and flexible photodetector system includes a triboelectric nanogenerator, TENG, device configured to generate an electrical current from a mechanical movement; a photodetector, PD, sensor, formed on the TENG device and configured to detect a light; and a voltage regulating circuit electrically connected to the TENG device and the PD sensor and configured to regulate a voltage provided by TENG device to the PD sensor. The PD sensor and the TENG device are flexible.

### CROSS-REFERENCE TO RELATED APPLICATIONS

This application claims priority to U.S. Provisional Patent Application No. 62/614,639, filed on Jan. 8, 2018, entitled “SELF-POWERED ORGANOMETALLIC HALIDE PEROVSKITE PHOTODETECTOR,” the disclosure of which is incorporated herein by reference in its entirety.

### BACKGROUND

### Technical Field

Embodiments of the subject matter disclosed herein generally relate to a photodetector with a very high detectivity, and more specifically, to a self-powered and flexible organometallic halide perovskite photodetector system.

### Discussion of the Background

Flexible, portable, and self-powered photodetectors (PDs) are highly desirable for applications in image sensing and optical communications. PDs with high detectivity can respond to weak optical signals. The PDs are also important for weak light detection, such as ambient light monitoring in smart buildings. Various types of semiconductors, including Si, InGaAs, ZnO, quantum dots, and organic polymers have been extensively explored for use in PDs with varying success. This is because these materials behave differently in term of their responsivity (R), detectivity (D*), and response time, largely due to their distinct bandgaps, spectral responses, and carrier mobility/diffusion lengths.

In the last few years, organometallic halide perovskites have attracted attention in optoelectronic applications due to their outstanding properties, such as, strong absorption in the ultraviolet (UV)-visible wavelengths, long carrier diffusion lengths, and widely tunable bandgaps. Furthermore, polycrystalline and single crystalline perovskite materials could be easily prepared from solution-process at low temperatures on flexible substrates. As a result of these advantages, organometallic halide perovskites have been employed in diverse optoelectronic devices, including solar cells, light-emitting diodes, and PDs. For example, Dou et al. (L. Dou, Y. M. Yang, J. You, Z. Hong, W.-H. Chang, G. Li, Y. Yang, Nat. Commun. 2014, 5, 5404) reported a solution-processed perovskite PD with high detectivity, and Saidamiov et al. (M. I. Saidaminov, V. Adinolfi, R. Comin, A. L. Abdelhady, W. Peng, I. Dursun, M. Yuan, S. Hoogland, E. H. Sargent, O. M. Bakr, Nat. Commun. 2015, 6, 8724) demonstrated a PD based on a single crystalline perovskite, which featured carrier diffusion lengths longer than the polycrystalline material. These results demonstrate the potential of perovskites as active materials in optoelectronic devices.

For self-powered applications, triboelectric nanogenerators (TENGs) have demonstrated promising capabilities in harvesting mechanical energy from motion produced from various sources such as humans, wind, and even water droplets. The advantages of TENGs include a high electrical output, simple design and fabrication, and a rich variety of materials that exhibit the triboelectric effect. Different types of sensing systems powered by TENGs are being developed, including those that can detect touch, vibrations, UV light, and molecules using low-cost, highly portable, and widely applicable designs. Moreover, sensors based on TENGs are self-powered (i.e., no external power or storage system is needed) and thus are highly favorable for operating in remote areas as well as outdoor applications.

Recently, researchers reported self-powered organometallic halide perovskite PDs driven by TENGs, in which the perovskite served as both the photoresponsive and triboelectric material (see, for example, L. Su, Z. Zhao, H. Li, Y. Wang, S. Kuang, G. Cao, Z. L. Wang, G. Zhu, J. Mater. Chem. C 2016, 4, 10395 and L. Su, Z. X. Zhao, H. Y. Li, J. Yuan, Z. L. Wang, G. Z. Cao, G. Zhu, ACS Nano 2015, 9, 11310). Unfortunately, the responsivity of these devices has been very limited since the triboelectric property of perovskites is not as good as the state-of-the-art triboelectric materials, such as polydimethylsiloxane (PDMS) and polyimides. Alternatively, the PD and TENG components can be separated into two parts of the device in order to achieve better performance, but this design substantially increases the bulkiness of the system, which is not favorable for practical use. Moreover, most TENG-powered PDs are driven by a motion actuator. Inconsistencies associated with the motion actuator can cause false signals to be detected.

Thus, there is a need for a new triboelectric PD system that is not limited by the above discussed drawbacks.

### SUMMARY

According to an embodiment, there is a self-powered and flexible photodetector system that includes a triboelectric nanogenerator, TENG, device configured to generate an electrical current from a mechanical movement; a photodetector, PD, sensor, formed on the TENG device and configured to detect a light; and a voltage regulating circuit electrically connected to the TENG device and the PD sensor and configured to regulate a voltage provided by TENG device to the PD sensor. The PD sensor and the TENG device are flexible.

According to another embodiment, there is a method for manufacturing a self-powered and flexible photodetector system. The method includes building a triboelectric nanogenerator, TENG, device which is configured to generate an electrical current from a mechanical movement; building a photodetector, PD, sensor, on the TENG device, the PD sensor being configured to detect a light; and electrically connecting a voltage regulating circuit to the TENG device and to the PD sensor, wherein the voltage regulating circuit is configured to regulate a voltage provided by TENG device to the PD sensor. The PD sensor and the TENG device are flexible.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic illustration of a self-powered, flexible, photodetector system;

FIG. 2 is a schematic illustration of a self-powered, flexible, photodetector system and its electrical connections;

FIG. 3 illustrates the voltage generated by the TENG system after multiple tapings;

FIGS. 4A and 4B illustrate the current response of the PD under direct voltage bias;

FIG. 5 illustrates the photocurrent and responsivity of the PD sensor by applying a DC voltage bias;

FIG. 6A illustrates the voltage at the perovskite layer when powered by TENG and having a voltage regulating circuit, and FIG. 6B illustrates the change in voltage (ΔV) and voltage responsivity when powered by TENG and having the voltage regulating circuit;

FIG. 7 illustrates a normalized voltage of self-powered PD systems while being powered by TENG, during prolonged operation at three different bending angles;

FIG. 8 illustrates the voltage response of the PD sensor under when powered by TENG, for various angles of incidence;

FIG. 9 is a flowchart of a method for making a PD system;

FIG. 10 illustrates a PD system having a voltage regulating circuit and a measuring device;

FIG. 11 is a flowchart of a method for making another PD system; and

FIG. 12 is a schematic diagram of a computing device in which a measuring device may be implemented.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. For simplicity, the following embodiments are discussed with regard to a self-powered flexible PD system that detects light. However, the embodiments are not limited to this specific case and one skilled in the art would understand that the PD system can be used as a solar cell or as part of other optoelectronics devices.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a self-powered and flexible PD sensor based on methylammonium lead iodide (CH₃NH₃PbI₃) perovskite is presented. Using a voltage regulating circuit, it is shown that the TENG-powered PD sensor can perform consistently even with an irregular motion, such as human finger tapping. This enables the PD system to work without a bulky external power source and/or motion actuator. In addition, a high-quality CH₃NH₃PbI₃ perovskite thin film was fabricated using solvent engineering, which enables the PD sensor to exhibit an impressive detectivity of 1.22×10¹³ Jones, suggesting applications for the detection of ambient-level light. When the PD sensor is being self-powered by the TENG device, it can achieve a large responsivity of up to 79.4 V per mW cm⁻² and a voltage response of up to ˜90% between the highest and lowest applied light intensities. The importance of resistance matching between the TENG device and the perovskite layer to the voltage response of the PD sensor is also discussed.

As the PD sensor discussed in this embodiment is made of flexible polymer films, it demonstrates no degradation in device performance after being bent for 1000 times. Because its polymer base is mostly transparent, the PD sensor also functions at 360° of illumination. In field tests done at different lighting conditions, the PD sensor can respond to various light intensities, including ambient light. As a result, the self-powered, flexible, 360° omnidirectional perovskite PD sensor of this embodiment features high detectivity and responsivity along with real-world sensing capability, suggesting its importance for next-generation optical communications, sensing and imaging applications.

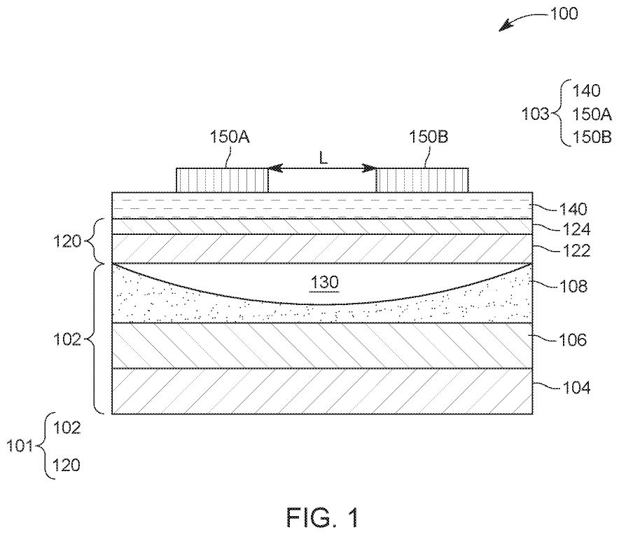

According to an embodiment illustrated in FIG. 1, a flexible, self-powered PD system 100 exhibits a high detectivity and responsivity. The flexible, self-powered PD system includes a power generating device 101 and a PD sensor 103. The PD sensor 103 is attached to the power generating device 101 and both of them are made, as discussed later, to be flexible. The power generating device 101 is a triboelectric nanogenerator (TENG), which is an energy harvesting device that converts the external mechanical energy into electricity by a triboelectric effect and/or electrostatic induction. The TENG device 101 includes a first compounded layer 102 mechanically connected to a second compounded layer 120 so that a gap 130 is formed between portions of the two compounded layers. A layer 140 of CH₃NH₃PbI₃ perovskite is formed over the second compounded layer 120 of the TENG device 101. Two electrodes 150A and 1508 are electrically connected to the CH₃NH₃PbI₃ perovskite layer 140. Although FIG. 1 shows the two electrodes formed on top of the CH₃NH₃PbI₃ perovskite layer 140, it is possible to place these two electrodes between the CH₃NH₃PbI₃ perovskite layer 140 and the second compounded layer 120, or it is also possible to place one electrode on top of the layer 140 and one electrode at the bottom of layer 140. The CH₃NH₃PbI₃ perovskite layer 140 acts as a photo-absorptive layer.

The first compounded layer 102 may include a first indium-doped tin-oxide (ITO) layer 104 and a first polyethylene terephthalate (PET) layer 106 that coats the first ITO layer 104. Thus, the first compounded layer 102 is a polymer film. The invention is not limited to an ITO layer 104 and a PET layer 106 for forming the first compounded layer 102. One or both of these two layers may be substituted with similar layers. The first compounded layer may also include a silicone layer 108, for example, polydimethylsiloxane (PDMS). The second compounded layer 120 may include a second ITO layer 122 and a second PET layer 124 that coats the second ITO layer 122.

Note that there are no other gaps between the layers shown in FIG. 1 except for the gap 130. The two electrodes 150A and 1508 may be made of gold. In one application, a distance L between the two electrodes is in the range of micrometers. For example, in one application, the distance L is about 100 μm.

The gap 130 between the first compounded layer 102 and the second compounded layer 120 may include air. The gap may have a size in the millimeters. In one application, the gap is about 5 mm. The purpose of the gap 130 is to allow one or both of the first and second compounded layers 102 and 120 to touch and separate relative to the other so that energy is generated. Note that for generating energy with the first and second compounded layers, the order of the sublayers of the first and second compounded layers need to be as shown in FIG. 1, i.e., PDMS layer 108 next to (partially in direct contact with) second ITO layer 122, and first PET layer 106 in direct contact with the PDMS layer 108.

A 5 mm gap between the two polymer compounded films 102 and 120 enables the PD sensor 103 to harness the triboelectrification effect generated between the ITO and PDMS layers as the device is physically manipulated, e.g., by finger tapping. Because of the ITO, PET, and PDMS layers, the PD sensor has a high transparency and flexibility. Because of the triboelectric effect between the ITO and PDMS layers, the PD system is self-powered as long as any motion is detected, i.e., as long as the gap 130 is mechanically changed by any means, e.g., human touch, wind, sea waves, etc.

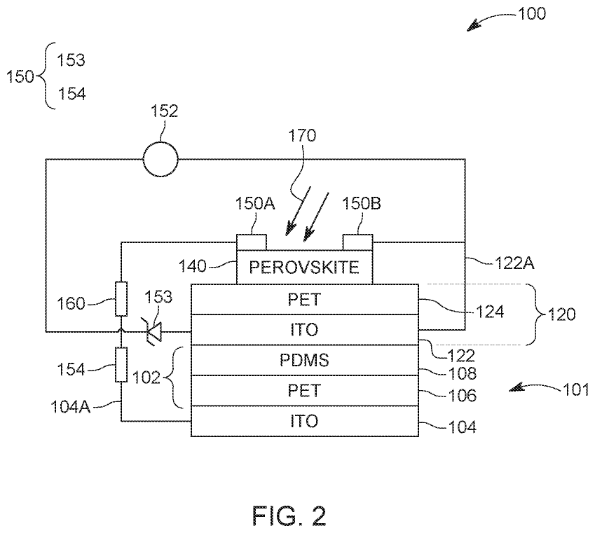

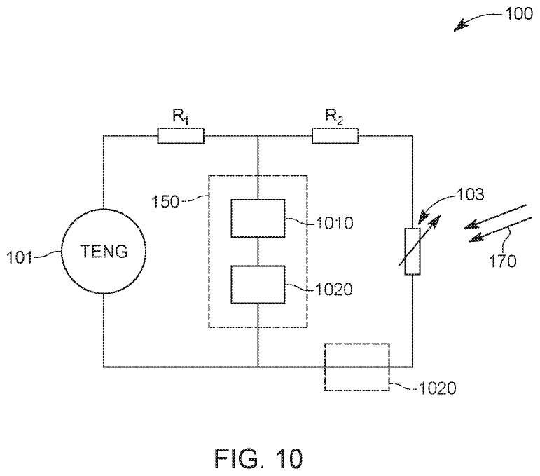

A detailed schematic of the self-powered PD system 100 indicating the multiple layers and electrical wire configuration is shown in FIG. 2. The self-powered PD system 100 is completed in this figure by connecting the two ITO layers 104 and 122 of the TENG device 101, to the gold electrodes 150A and 150B through corresponding wires 104A and 122A. The equivalent circuit diagram is shown in FIG. 10.

FIG. 2 also shows a voltage regulator 150 and a resistor 160 connected to the wire 104A. A Zenner diode, which is part of the voltage regulator 150, is connected between the ITO layer 122 and a resistor 154, which is also part of the voltage regulator 150. A voltage monitor 152 may be placed as illustrated in FIG. 2 to measure a voltage between electrode 150B and resistor 160. The reason for adding the voltage regulator circuit 150 and the resistor 160 is as follows.

When the photo-absorptive perovskite layer 140 is illuminated by light 170, as illustrated in the figure, the resistivity of the layer 140 decreases due to the photogenerated carriers. Therefore, the electric potential difference across the perovskite layer 140 decreases when the voltage generated by the TENG device 101 is divided by the perovskite layer 140 and the resistor 160. In one application, the resistor 160 is a large resistor. For example, resistor 160 may be about 10 MΩ. Other values may be used.

Utilizing this principle, the intensity of the incident light 170 can be detected by monitoring a voltage V across the perovskite layer 140. Note that the voltage output of the TENG device 101 is modulated by the voltage regulating circuit 150, which may include a resistor 154 and a Zener diode 153. In one embodiment, the voltage regulating circuit may include more sophisticated components, e.g., transistors or other semiconductor devices. Other components may be used for the voltage regulating circuit. This voltage regulating circuit enables the self-powered PD system to function consistently and quantitatively even as it is powered by irregular motion, thus circumventing the need for a bulky motion actuator.

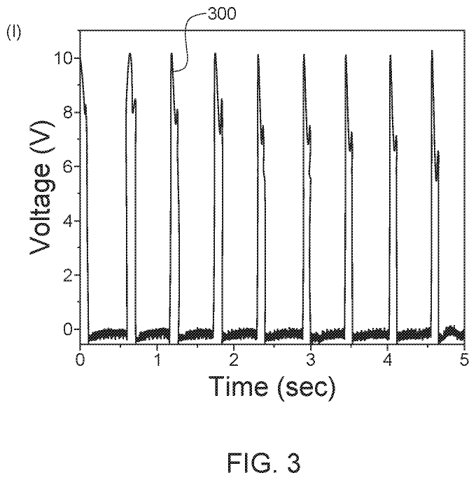

FIG. 3 illustrates the resulting highly regulated voltage output 300 of the TENG system 101. This regulated voltage output is especially desired for the PD system because the detected voltage should solely depend on the intensity of the incident light. The spikes in the voltage output 300 correspond to the finger tapping of the TENG device 101.

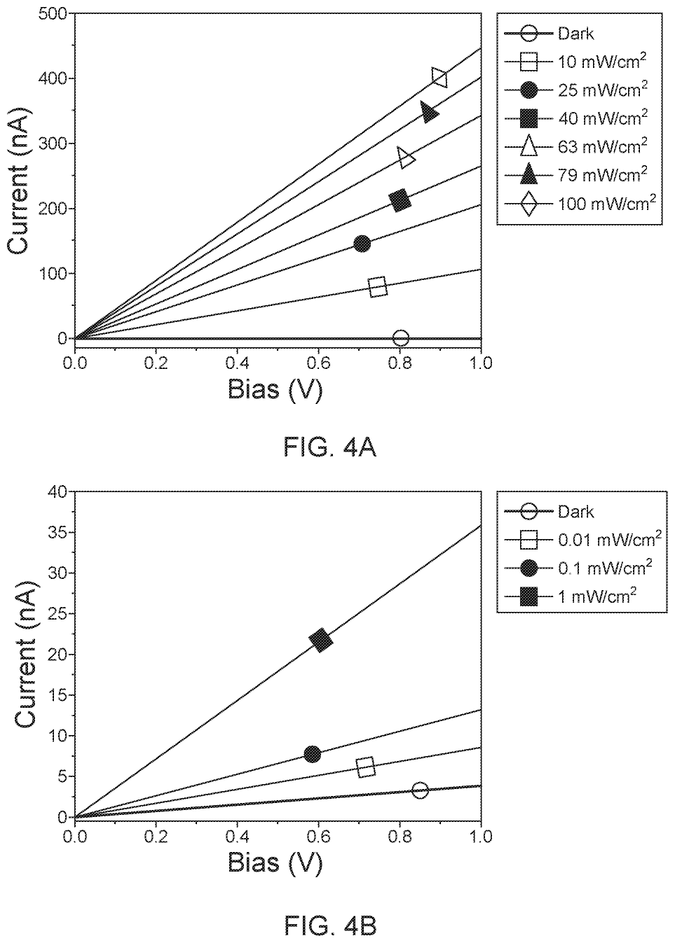

To quantitatively characterize the CH₃NH₃PbI₃ perovskite PD system 100, its current-voltage (I-V) performance was measured using a 1 V bias at different light intensities (10 μW/cm² to 100 mW/cm²) by attenuating 1-sun (100 mW/cm²) simulated sunlight using neutral density filters. The current-voltage curves are shown in FIGS. 4A and 4B. The photocurrent increases with the light intensity as expected due to the increased number of photogenerated carriers in response to the higher photon flux. FIG. 4B shows the photocurrent of the perovskite PD under weak light intensity, as low as 10 μW/cm². Even at this low intensity, it is noted that the resulting photocurrent is still two-fold higher than the one under dark conditions. It can be seen that the perovskite PD system behaves as other normal CH₃NH₃PbI₃ perovskites in term of the chemical stability. It was also determined that the response time of the perovskite PD sensor was less than 80 ms, which is the detection limit of the used setup.

Detectivity (D*) is a parameter that indicates the ability of a PD sensor to measure weak optical signals. D* is given by Equation (1):

$${D}^{*} = \frac{R}{\sqrt{2 {qI}_{Dark}}} , \qquad ( 1 )$$

in which R is the responsivity, I_{dark} is the dark current, and q is the elementary charge. In addition to the unique self-powered capability of the system 100, the perovskite PD sensor illustrated in FIGS. 1 and 2 exhibits a detectivity as high as 1.22×10¹³ Jones in the conventional current detection mode, which is comparable to the performance of state-of-the-art PDs based on Si (the most common PD material) and among the highest when compared with other organometallic halide perovskites based PDs. It is noted that the detectivity was not calculated in the self-powered operation mode due to the insufficient current output by the TENG. This high detectivity of the PD system 100 is believed to be due to the strong optical absorption of the CH₃NH₃PbI₃ layer and the high quality perovskite film obtained by solvent engineering. This process involved the drop-by-drop addition of toluene to the CH₃NH₃PbI₃ precursor solution while spin-coating in order to form an intermediate phase that prevents rapid reaction between the CH₃NH₃I and PbI₂, which is discussed later. As a result, a highly dense and uniform perovskite thin film was formed, which efficiently suppresses photogenerated carrier recombination.

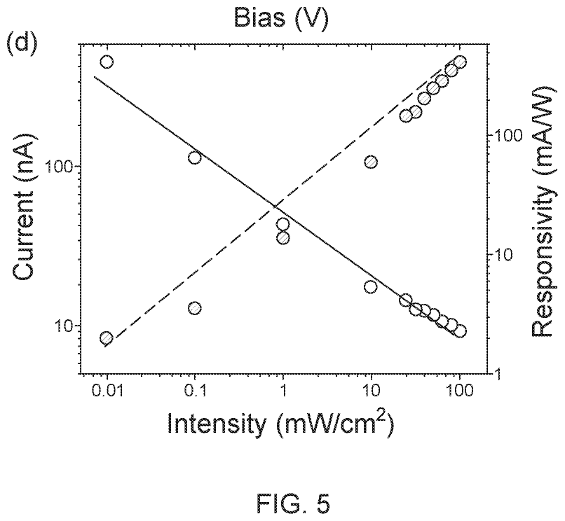

The PD's photoresponse and responsivity (R) were also calculated both in conventional current detection mode (by applying a bias across the perovskite layer) and in self-powered voltage detection mode. FIG. 5 illustrates the photocurrent and responsivity of the PD under different light intensities. The responsivity of the PD system 100, indicating how efficient the detector responds to the optical signal, is calculated by Equation (2):

$$R = \frac{{I}_{ph}}{{P}_{light}} , \qquad ( 2 )$$

in which Iₚₕ is the photocurrent and P_{light} is the power of the incident light. Based on this equation, it was determined that the perovskite based PD system 100 achieves a responsivity as high as 0.418 A/W at 10 μW/cm². It is worth noting that this value is not the highest ever reported for perovskite PDs because the resistance of the PD sensor in this embodiment has been intentionally increased by adjusting the channel width in order to accommodate the internal resistance of the TENG device and maximize the sensitivity in the self-powered voltage detection mode.

In self-powered voltage detection mode, the perovskite PD sensor is connected in series with a 10 MΩ resistor at the output of the TENG device. The perovskite layer acts as a variable resistor with its resistance being modulated by the incident light intensity. In fact, the TENG device can be regarded as a battery with a very high internal resistance. Thus, if the resistance of the perovskite PD sensor is too low, the electric potential drop at the perovskite layer would be too small or negligible. Accordingly, according to an embodiment, the resistance of the perovskite PD sensor was optimized in order to maximize the response in the self-powered voltage detection mode.

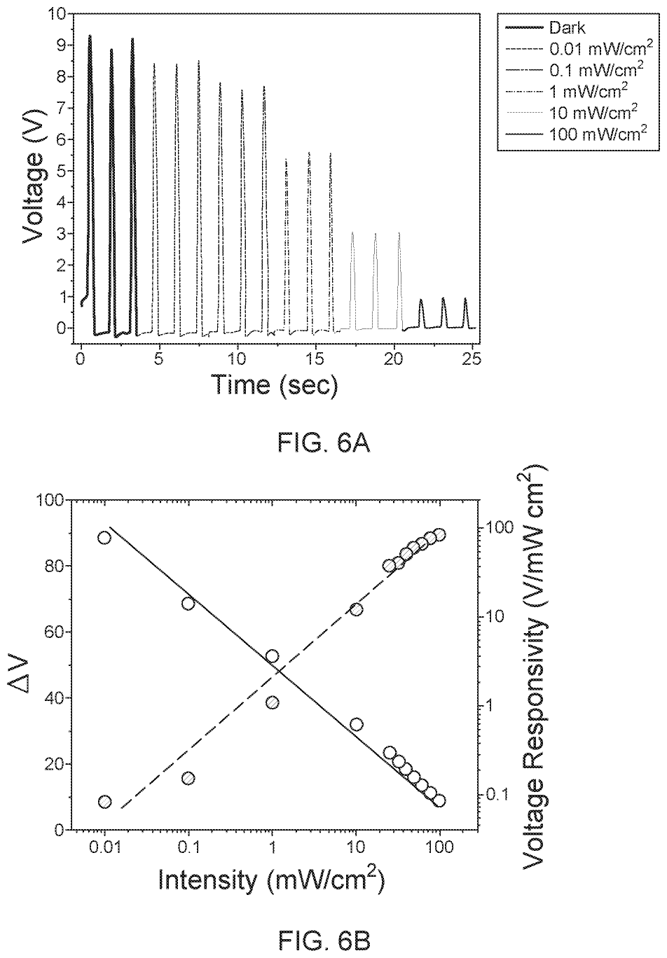

FIG. 6A shows the voltage at the perovskite layer when powered by TENG (under various light intensities, from dark to 100 mW/cm²). The voltage drop at the perovskite layer decreases with the light intensity because its resistance is reduced by the photogenerated carriers. To evaluate the performance of the PD in the voltage detection mode, the change in voltage (ΔV) and voltage responsivity has been measured, as shown in FIG. 6B, which are defined as

$$\frac{( {V}_{Dark} - V )}{{V}_{Dark}} \times 100 \% and \frac{{V}_{Dark} - V}{{P}_{Light}} ,$$

respectively. The results demonstrate that the PD system 100 can achieve a large AV of up to ˜90% at an incident light intensity of 100 mW/cm² compared to the dark, which demonstrates the excellent sensitivity of the self-powered perovskite PD system. This impressive voltage response can be attributed to the optimized resistance matching between the TENG device 101 and the perovskite based PD sensor 103. Moreover, the steepest ΔV occurred between light intensities of 10 μW/cm² to 25 mW/cm², which suggests that the perovskite PD sensor 103 is more sensitive under weak light conditions. Meanwhile, the PD system 100 reaches a maximum voltage responsivity of 79.4 V per mW/cm², which is a remarkably high value that benefits from the large and stable voltage output of the TENG device 101. Additionally, it is observed that the TENG device used in this embodiment was regulated at 10 V, which is a relatively small voltage. It is expected that the responsivity of the PD sensor 103 could be even further enhanced if using TENGs featuring higher voltage outputs.

Another advantage of the TENG-powered perovskite PD system 100 is its flexibility during operation. This means the PD system 100 can be fabricated on either rigid or flexible substrates, which means that this device can be used in real-world applications, such as ambient light monitoring in smart buildings, optical communications, etc.

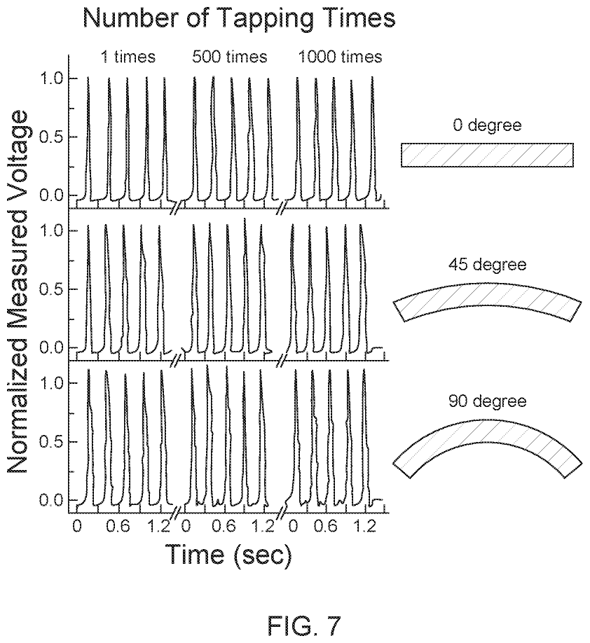

Additionally, the PD system 100 shows excellent performance stability while being repeatedly bent. FIG. 7 displays the normalized voltage of self-powered PD systems 100 during prolonged operation at three different bending angles, including 0° (non-bended), 45°, and 90° under 1-sun illumination. For each bending angle, the voltage has been measured after the PD system had been powered by finger tapping 1, 500, and 1,000 times. The performance of the PD systems was very stable at these different angles of curvature, as the voltage remained unchanged even while the system was powered by 1,000 repetitions of finger taping.

It was observed that the normalized voltages slightly increased when the PD system was bent at 45° and 90°, which implies that the resistance of the perovskite layer 140 increased slightly in both cases. This can be explained by the appearance of micro-cracks as the system was bent. These micro-cracks hinder the collection of photogenerated charge carriers, resulting in a larger voltage drop in the perovskite active layer.

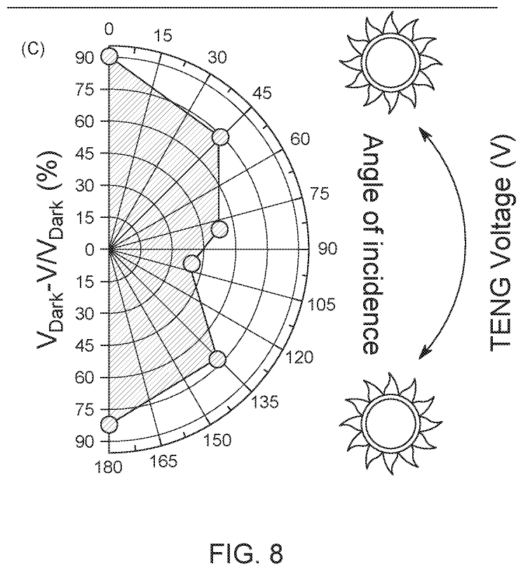

Because the PD system was fabricated with transparent materials, including PDMS, PET, and ITO layer, the system can function whether it is illuminated from the top or the bottom. This advantage of the PD system 100 is illustrated in FIG. 8, which shows a plot of ΔV when powered by TENG, under various angles of incidence, in which 0° refers to illumination from the top-side of the system and 180° refers to illumination from beneath the PD system 100. When the angle of incidence was increased to 45° and 80°, the ΔV was reduced due to a stronger surface reflection, which results in less optical absorption by the perovskite layer. Moreover, the ΔV for the illumination from the backside of the PD system 100 was slightly lower than that for illumination from the top, which can be explained by the parasitic absorption of the ITO layer.

The results presented in FIGS. 7 and 8 demonstrate that the PD system 100 features omnidirectional light-harvesting capabilities, and good durability under various bending conditions.

Conventional TENG-powered devices require a motion actuator to power the system during operation. However, the voltage output by the TENG device might be variable, depending on how the surrounding conditions influence the actuator's motion, which can affect the accuracy of photo-detection. The PD system 100 utilizes a voltage regulating circuit 150 to ensure the detected voltage only depends on the light intensity, rather than the mechanical pressure being applied to the TENG device 101. This feature makes the PD system 100 to have a very accurate response to the incident light, which is not the case for the existing systems that uses a TENG device as the power source.

Furthermore, this design allows the PD system to function properly even under irregular mechanical motions, which greatly enhances the versatility of the system. For example, the results presented in the previous figures were obtained by powering the PD system by finger tapping. Further, the PD system 100 was tested by finger tapping by two different persons. The two sets of the TENG output generated by the two different persons shows results that are highly consistent, which is important for ensuring the accuracy in the self-powered voltage detection mode.

Besides systematically characterizing the PD system 100 in the lab, field tests were also performed to investigate the system's performance under different environments, including sunny, cloudy, and indoor lighting conditions. The photo-to-dark current ratio (PDCR, defined as

$$\frac{( {I}_{Light} - {I}_{Dark} )}{{l}_{Dark}}$$

and the ΔV of the PD sensor, which represent the results from the conventional current detection mode and the self-powered voltage-detection mode, respectively, exhibit the same trend. In this regard, the PD system exhibited a ΔV of 58%, 45%, and 16% on sunny, cloudy, and room lighting conditions, respectively, which shows the PD system can clearly distinguish between different levels of light. This performance is ascribed to the optimized resistance matching between the perovskite PD sensor 103 and the TENG device 101. These results demonstrate the strong functionality and sensitivity of the self-powered PD system 100 in real-world environments.

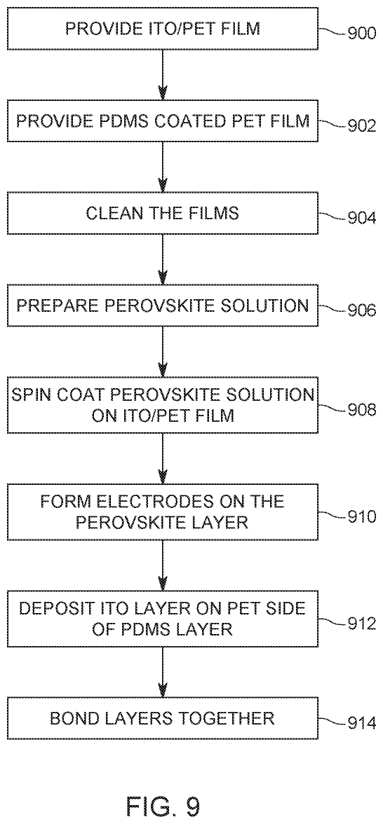

A method of fabricating the PD system 100 is now discussed with regard to FIG. 9. In step 900, a ITO/PET film is provided. For example, the ITO/PET film may have a size of about 5.5 cm×5 cm with a resistivity of 100 Ω/sq area. In step 902, a PDMS coated PET film is provided. The PDMS coated PET film may have a 5 cm×5 cm size. The two films are cleaned with acetone, isopropanol, and de-ionized water in step 904.

In step 906, a 1:1 molar ratio of CH₃NH₃I and PbI₂ are dissolved in a solution composed of gamma-butyrolactone and dimethyl sulfoxide (3:2, v/v) at 50° C. for 24 h. The perovskite solution may be filtered (PTFE filter, 0.45 um pore size) and then spin-coated in step 908 onto the ITO/PET film (layer 120 in FIG. 1) obtained in step 900. In one application, a 1.5×1.5 cm² area of the ITO/PET film is defined by Kapton tape, on the PET side 124 of the ITO/PET film 120, and the perovskite solution is coated in that defined area. In one application, spin-coating involves two stages at 5,000 rpm and 1,000 rpm for 20 s and 10 s, respectively. Other values may be used. The result of the spin-coating process is the formation of the perovskite layer 140.

In step 908, approximately 50 μL of toluene was added drop-by-drop during the second stage of spin-coating to form an intermediate phase that prevented the CH₃NH₃I and PbI₂ reagents from reacting too quickly, thus enabling a uniform CH₃NH₃PbI₃ film to be deposited onto the PET film 124 surface. Two 40 nm thick gold electrodes were then deposited in step 910, 100 μm apart, on top of the perovskite layer 140, by e-beam evaporation. Other methods may be used or the electrodes may be formed on different faces of the perovskite layer 140, as previously discussed.

For the second compounded layer 102 of the TENG device 101, the method deposited in step 912 a 200 nm thick layer of ITO 104 on the PET 106 side of the PDMS layer 108 from step 902, by, for example, DC magnetron sputtering. In step 914, the two compounded layers 102 and 120 were bonded together with the ITO 122 side of the ITO/PET film 102, facing the PDMS layer 108 of the second compounded layer 120, using any available bonding method. In one application, Kapton tape was used to bond the two compounded layers 102 and 120. A small gap, for example, of about 5 mm, was left between the two compounded layers 102 and 122 (see FIG. 1) because one layer was made to be slightly longer than the other compounded layer.

The voltage regulating circuit 150 shown in FIG. 2 has a Zener diode 153 and a resistor 154. The voltage regulating circuit is designed to limit the output voltage of the TENG device 101. For these reasons, the Zener diode 153 allows a wide range of currents when a reverse voltage exceeds a threshold value, which is called the Zener voltage. In one embodiment, a Zener diode with a Zener voltage of 10 V has been selected and it was connected to the output of the TENG device 101. As a result, the voltage of the TENG device is regulated at 10 V.

However, it is possible to replace the Zener diode with a more complex structure. For example, as illustrated in FIG. 10, the PD system 100 may have a voltage regulating circuit 150 that includes an integrated circuit 1010. The integrated circuit may be programed to achieve the function of the Zener diode in the embodiment of FIG. 2. Alternatively, the integrated circuit 1010, which includes at least a memory and a processor, may store software instructions for regulating the voltage generated by the TENG device 101 with any desired value. Further, the voltage regulating circuit 150 may also include, in one embodiment, a measurement device 1020 (e.g., voltage or current sampling circuit), that is configured to measure a voltage across the PD sensor 103 or a current passing through the PD sensor 103. As illustrated in FIG. 10, the measuring device 1020 may be placed inside the voltage regulating circuit 150, in parallel to the PD sensor 103, or in series with the PD sensor 103. The measuring device 1020 may include a processor for sampling and detecting the measured quantity. In one embodiment, the measurement device may be an amperemeter, voltmeter, oscilloscope, or a device that achieves the same functions as these devices.

The processor of the voltage regulating circuit 150 or the processor of the measuring device 1020 or another processor may be used for associating the change in the measured parameter (e.g., current or voltage or resistivity) with an intensity I of the light 170 falling on the PD sensor. In this way, the measured intensity I of the PD sensor may be used for optical communications, or for managing the illumination of a building, or for any other application in which a PD sensor is used.

Thus, according to the embodiments discussed above, a self-powered, flexible and transparent organometallic halide perovskite PD system 100 has been obtained. The photodetector sensor 103 is versatile and exhibits stable prolonged operation under different bending angles, different environments, and varying incident angles of light. The PD sensor 103 also exhibits an impressive detectivity of 1.22×10¹³ Jones in the current detection mode, and a large responsivity of up to 79.4 V per mW/cm² in the self-powered voltage detection mode. These results were made possible through the use of a high quality CH₃NH₃PbI₃ thin film 140, which was achieved using solvent engineering. In addition, the PD sensor 103 demonstrates a voltage response of up to ˜90% between the highest and lowest applied light intensities, which can be attributed to the optimized resistance matching between the TENG device 101 and the PD sensor 103. More importantly, with the voltage regulating circuit 150, the self-powered PD system 100 functions with regular precision even as irregular mechanical forces are applied, such as by human finger tapping, all without the aid of a bulky external power system or motion actuator. These results demonstrate a simple and promising approach for developing a flexible and self-powered sensing system for applications such as smart textiles and smart buildings.

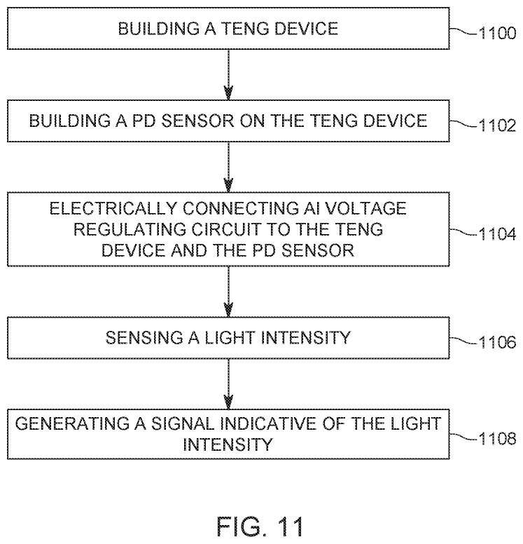

A method for making a self-powered and flexible photodetector system 100 is now discussed with regard to FIG. 11. The method includes a step 1100 of building a triboelectric nanogenerator, TENG, device 101 which is configured to generate electrical current from mechanical movement, a step 1102 of building a photodetector, PD, sensor 103, on the TENG device 101, the PD sensor being configured to detect light, and a step 1104 of electrically connecting a voltage regulating circuit 150 to the TENG device 101 and to the PD sensor 103. The voltage regulating circuit is configured to regulate a voltage provided by TENG device 101 to the PD sensor 103. A method for making each component of the TENG device and the PD sensor has been discussed above with regard to FIG. 9. Other methods or variations of the method discussed with regard to FIG. 9 may be used.

The method may further include a step 1106 of sensing with the PD sensor a light intensity, and producing in step 1108, with a measuring device 1020, a signal indicative of the measured light intensity. The measuring device 1020 may also process (e.g., amplifies, digitize, etc.) the measured light intensity and/or the signal. In one application, the signal may be used by other devices to switch on or off a light, a machine. In another application, the signal may be used along an optical cable or fiber for transmitting information. The measuring device is powered with energy obtained from a TENG device. The TENG device may be powered, for example, by a finger tap, movement of the optical cable in the ocean to the water waves, etc.

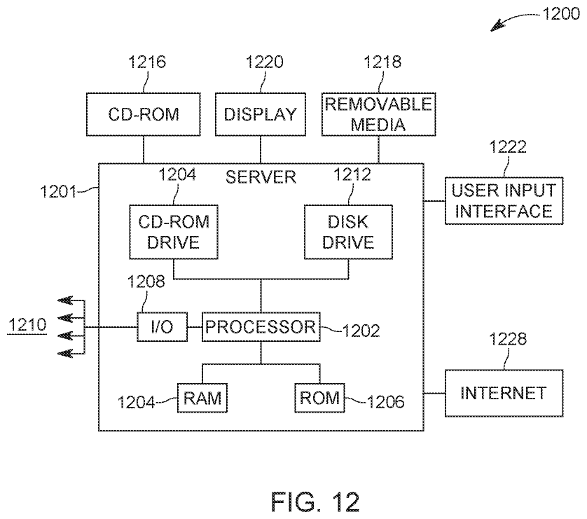

The above-discussed procedures and methods may be implemented in a computing device or controller as illustrated in FIG. 12. Hardware, firmware, software or a combination thereof may be used to perform the various steps and operations described herein. Computing device 1200 of FIG. 12 is an exemplary computing structure that may be used in connection with such a system. In one application, voltage regulating circuit 1010 or measuring device 1020 shown in FIG. 10 can be implemented as the computing device 1200.

Exemplary computing device 1200 suitable for performing the activities described in the exemplary embodiments may include a server 1201. Such a server 1201 may include a central processor (CPU) 1202 coupled to a random access memory (RAM) 1204 and to a read-only memory (ROM) 1206. ROM 1206 may also be other types of storage media to store programs, such as programmable ROM (PROM), erasable PROM (EPROM), etc. Processor 1202 may communicate with other internal and external components through input/output (I/O) circuitry 1208 and bussing 1210 to provide control signals and the like. Processor 1202 carries out a variety of functions as are known in the art, as dictated by software and/or firmware instructions.

Server 1201 may also include one or more data storage devices, including hard drives 1212, CD-ROM drives 1214 and other hardware capable of reading and/or storing information, such as DVD, etc. In one embodiment, software for carrying out the above-discussed steps may be stored and distributed on a CD-ROM or DVD 1216, a USB storage device 1218 or other form of media capable of portably storing information. These storage media may be inserted into, and read by, devices such as CD-ROM drive 1214, disk drive 1212, etc. Server 1201 may be coupled to a display 1220, which may be any type of known display or presentation screen, such as LCD, plasma display, cathode ray tube (CRT), etc. A user input interface 1222 is provided, including one or more user interface mechanisms such as a mouse, keyboard, microphone, touchpad, touch screen, voice-recognition system, etc.

Server 1201 may be coupled to other devices, such as a smart device, e.g., a phone, tv set, computer, etc. The server may be part of a larger network configuration as in a global area network (GAN) such as the Internet 1228, which allows ultimate connection to various landline and/or mobile computing devices.

The disclosed embodiments provide methods and mechanisms for detecting light with a self-powered, flexible, PD system. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A self-powered and flexible photodetector system comprising:
a triboelectric nanogenerator, TENG, device configured to generate an electrical current from a mechanical movement;
a photodetector, PD, sensor, formed on the TENG device and configured to detect a light; and
a voltage regulating circuit electrically connected to the TENG device and the PD sensor and configured to regulate a voltage provided by TENG device to the PD sensor,
wherein the PD sensor and the TENG device are flexible.

2. The system of claim 1, wherein the TENG device includes a first compounded layer separated by a gap G from a second compounded layer, the first and second compounded layers being bonded to each other at certain locations.

3. The system of claim 2, wherein a movement of one of the first and second compounded layers relative to another of the first and second compounded layers generates an electrical current.

4. The system of claim 2, wherein the first compounded layer includes a polydimethylsiloxane (PDMS) layer, a first polyethylene terephthalate (PET) layer, and a first indium-doped tin-oxide (ITO) layer, the PDMS and the first ITO layers sandwiching the PET layer.

5. The system of claim 4, wherein the second compounded layer includes a second PET layer and a second ITO layer.

6. The system of claim 5, wherein the PD sensor includes an organometallic halide perovskite layer.

7. The system of claim 6, wherein the organometallic halide perovskite layer includes CH₃NH₃PbI₃.

8. The system of claim 7, wherein the organometallic halide perovskite layer is formed directly on the second PET layer of the second compounded layer of the TENG device.

9. The system of claim 5, wherein the gap is formed directly between the second ITO layer of the second compounded layer of the TENG device and the PDMS layer of the first compounded layer of the TENG device.

10. The system of claim 1, further comprising:
two electrodes formed on the PD sensor, one electrode electrically connected to the first compounded layer of the TENG device and the other electrode connected to the second compounded layer of the TENG device.

11. The system of claim 1, wherein the TENG device and the PD sensor are transparent.

12. The system of claim 1, wherein the PD sensor is formed directly on the TENG device.

13. The system of claim 1, wherein the voltage regulating circuit includes a Zener diode and a resistor.

14. A method for manufacturing a self-powered and flexible photodetector system, the method comprising:
building a triboelectric nanogenerator, TENG, device which is configured to generate an electrical current from a mechanical movement;
building a photodetector, PD, sensor, on the TENG device the PD sensor being configured to detect a light; and
electrically connecting a voltage regulating circuit to the TENG device and to the PD sensor, wherein the voltage regulating circuit is configured to regulate a voltage provided by TENG device to the PD sensor,
wherein the PD sensor and the TENG device are flexible.

15. The method of claim 14, wherein the step of building the TENG device comprises:
forming a first compounded layer; and
forming a second compounded layer, the first and second compounded layers being bonded to each other at certain locations and having a gap between them at other locations.

16. The method of claim 15, wherein the step of forming the first layer comprises:
coating a polydimethylsiloxane (PDMS) layer with a first polyethylene terephthalate (PET) layer, and
forming a first indium-doped tin-oxide (ITO) layer over the first PET layer, the PDMS and the first ITO layers sandwiching the first PET layer.

17. The method of claim 16, wherein the step of forming the second compounded layer comprises:
coating a second PET layer over a second ITO layer.

18. The method of claim 17, further comprising:
spin-coating a solution of CH₃NH₃I and PbI₂ over the second PET layer to form an organometallic halide perovskite layer.

19. The method of claim 18, further comprising:
adding toluene, drop-by-drop, during the step of spin-coating.

20. The method of claim 18, wherein the step of spin-coating comprises:
dissolving the CH₃NH₃I and PbI₂ in a solution composed of gamma-butyrolactone and dimethyl sulfoxide;
spin-coating the solution with a first spinning speed on the second PET layer; and
spin-coating a remainder of the solution with a second spinning speed, smaller than the first spinning speed, while adding toluene drop-by-drop.
